(19) United States
(12) Patent Application Publication
(10) Pub. No.: US 2024/0162207 A1
(43) Pub. Date: May 16, 2024

(54) PASSIVE ELECTRONIC COMPONENTS ON A SEMICONDUCTOR DIE

(71) Applicant: Micron Technology, Inc., Boise, ID (US)

(72) Inventors: Kelvin Aik Boo TAN, Singapore (SG); Hong Wan NG, Singapore (SG); See Hiong LEOW, Singapore (SG); Seng Kim YE, Singapore (SG); Ling PAN, Singapore (SG)

(21) Appl. No.: 18/497,637

(22) Filed: Oct. 30, 2023

Related U.S. Application Data
(60) Provisional application No. 63/383,976, filed on Nov. 16, 2022.

(51) Int. Cl. H01L 25/16; H01L 23/00

(52) U.S. Cl. CPC H01L 25/165; H01L 24/48; H01L 25/0652

(57) ABSTRACT

Implementations described herein relate to various semiconductor device assemblies. In some implementations, a semiconductor package includes a substrate, a semiconductor die disposed on the substrate, and a passive electronic component disposed on the semiconductor die.

### CROSS REFERENCE TO RELATED APPLICATION

This Patent application claims priority to U.S. Provisional Patent Application No. 63/383,976, filed on Nov. 16, 2022, and entitled “PASSIVE ELECTRONIC COMPONENTS ON A SEMICONDUCTOR DIE.” The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to passive electronic components on a semiconductor die.

### BACKGROUND

A semiconductor package includes a casing that contains one or more semiconductor devices, such as integrated circuits. Semiconductor device components may be fabricated on semiconductor wafers before being diced into die and then packaged. A semiconductor package protects internal components from damage and includes means for connecting internal components to external components (e.g., a circuit board), such as via balls, pins, or leads. A semiconductor package is sometimes referred to as a semiconductor device assembly.

### BRIEF DESCRIPTION OF THE DRAWINGS

FIG. 1 is a diagram of an example apparatus that may be manufactured using techniques described herein.

FIG. 2 is a diagram of an example memory device that may be manufactured using techniques described herein.

FIG. 3 is a diagram of an example apparatus.

FIG. 4 is a diagram of an example apparatus.

FIG. 5 is a diagram of an example apparatus.

FIG. 6 is a flowchart of an example method of forming an integrated assembly or memory device having a passive electronic component on a semiconductor die.

FIG. 7 is a flowchart of an example method of forming an integrated assembly or memory device having a passive electronic component on a semiconductor die.

### DETAILED DESCRIPTION

A semiconductor package (e.g., a ball-grid array, solid-state drive device) may include a substrate that supports one or more semiconductor devices, such as one or more semiconductor dies and/or semiconductor die stacks. In addition to the semiconductor devices, a plurality of passive electronic components, such as resistors, inductors, and/or capacitors, used in connection with the semiconductor devices may be arranged on the substrate. The substrate may include limited area for these components, thereby constraining design options for the semiconductor package. Moreover, the placement of these components on the substrate may restrict routing for the semiconductor package. In general, a form factor of the semiconductor package should be minimized to facilitate miniaturization of a device that includes the semiconductor package and/or to meet applicable standards (e.g., a standard footprint of a semiconductor package is 16 millimeters (mm) by 20 mm). In some cases, to achieve this, one or more passive electronic components may be located outside of the semiconductor package, thereby increasing an overall footprint associated with the semiconductor package.

Some implementations described herein provide a semiconductor device assembly, such as a semiconductor package, in which one or more passive electronic components may be located on a semiconductor die (e.g., of a semiconductor die stack) that is disposed on a substrate. By using a surface of the semiconductor die (e.g., the semiconductor die stack) for placement of passive electronic components, passive electronic components that may have otherwise been located outside of the semiconductor device assembly may be arranged within a footprint of the semiconductor device assembly. In this way, an overall footprint associated with the semiconductor device assembly may be reduced, thereby facilitating miniaturization of a device that includes the semiconductor device assembly. Moreover, placement of passive electronic components on the semiconductor die (e.g., the semiconductor die stack) may facilitate the use of a greater quantity of passive electronic components in the semiconductor device assembly without increasing a size of the semiconductor device assembly. The greater quantity of passive electronic components may allow for enhancements to the complexity, operation, and/or functionality of the semiconductor device assembly. Furthermore, placement of passive electronic components on the semiconductor die (e.g., the semiconductor die stack) may free up area on the substrate (e.g., a primary layer), thereby increasing an amount of area on the substrate that may be used for routing and facilitating improved routing efficiency. In this way, the semiconductor device assembly may be associated with improved signal integrity and power integrity.

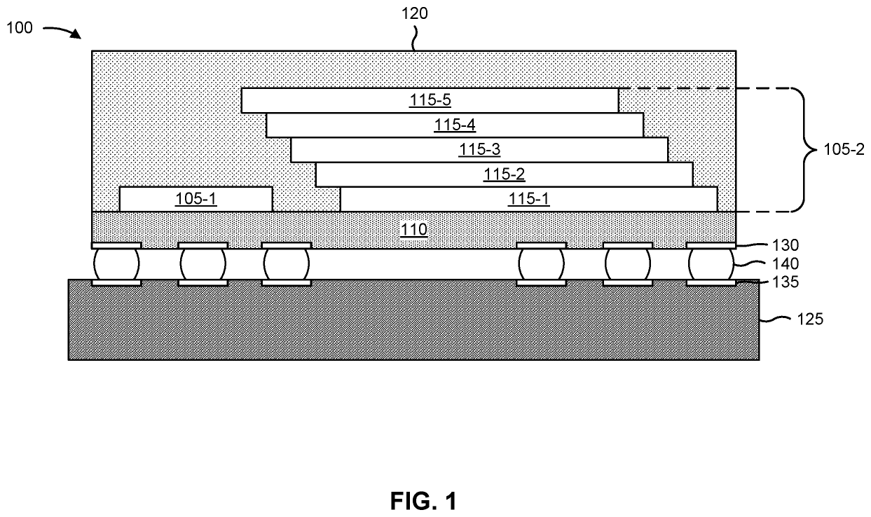

FIG. 1 is a diagram of an example apparatus 100 that may be manufactured using techniques described herein. The apparatus 100 may include any type of device or system that includes one or more integrated circuits 105. For example, the apparatus 100 may include a memory device, a flash memory device, a NAND memory device, a NOR memory device, a random access memory (RAM) device, a read-only memory (ROM) device, a dynamic RAM (DRAM) device, a static RAM (SRAM) device, a solid state drive (SSD), a microchip, and/or a system on a chip (SoC), among other examples. In some cases, the apparatus 100 may be referred to as a semiconductor package, an assembly, a semiconductor device assembly, or an integrated assembly.

As shown in FIG. 1, the apparatus 100 may include one or more integrated circuits 105, shown as a first integrated circuit 105-1 and a second integrated circuit 105-2, disposed on a substrate 110. An integrated circuit 105 may include any type of circuit, such as an analog circuit, a digital circuit, a radiofrequency (RF) circuit, a power supply, an input-output (I/O) chip, an application-specific integrated circuit (ASIC), a field-programmable gate array (FPGA), and/or a memory device (e.g., a NAND memory device, a NOR memory device, a RAM device, or a ROM device). An integrated circuit 105 may be mounted on or otherwise disposed on a surface of the substrate 110. Although the apparatus 100 is shown as including two integrated circuits 105 as an example, the apparatus 100 may include a different number of integrated circuits 105.

In some implementations, an integrated circuit 105 may include multiple semiconductor dies 115 (sometimes called dies), shown as five semiconductor dies 115-1 through 115-5. As shown in FIG. 1, the dies 115 may be stacked on top of each other to reduce a footprint of the apparatus 100. The stacked dies 115 may include three-dimensional electrical interconnects, such as through-silicon vias (TSVs), to route electrical signals between dies 115. Although the integrated circuit 105-2 is shown as including five dies 115, an integrated circuit 105 may include a different number of dies 115 (e.g., at least two dies 115). A first die 115-1 (sometimes called a bottom die or a base die) may be disposed on the substrate 110, a second die 115-2 may be disposed on the first die 115-1, and so on.

The apparatus 100 may include a casing 120 that protects internal components of the apparatus 100 (e.g., the integrated circuits 105) from damage and environmental elements (e.g., particles) that can lead to malfunction of the apparatus 100. The casing 120 may be a plastic (e.g., an epoxy plastic), a ceramic, or another type of material depending on the functional requirements for the apparatus 100.

In some implementations, the apparatus 100 may be included as part of a higher level system (e.g., a computer, a mobile phone, a network device, an SSD, a vehicle, or an Internet of Things device), such as by electrically connecting the apparatus 100 to a circuit board 125, such as a printed circuit board. For example, the substrate 110 may be disposed on the circuit board 125 such that electrical contacts 130 (e.g., bond pads) of the substrate 110 are electrically connected to electrical contacts 135 (e.g., bond pads) of the circuit board 125.

In some implementations, the substrate 110 may be mounted on the circuit board 125 using solder balls 140 (e.g., arranged in a ball grid array), which may be melted to form a physical and electrical connection between the substrate 110 and the circuit board 125. Additionally, or alternatively, the substrate 110 may be mounted on and/or electrically connected to the circuit board 125 using another type of connector, such as pins or leads. Similarly, an integrated circuit 105 may include electrical pads (e.g., bond pads) that are electrically connected to corresponding electrical pads (e.g., bond pads) of the substrate 110 using electrical bonding, such as wire bonding, bump bonding, or the like. The interconnections between an integrated circuit 105, the substrate 110, and the circuit board 125 enable the integrated circuit 105 to receive and transmit signals to other components of the apparatus 100 and/or the higher level system.

As indicated above, FIG. 1 is provided as an example. Other examples may differ from what is described with regard to FIG. 1.

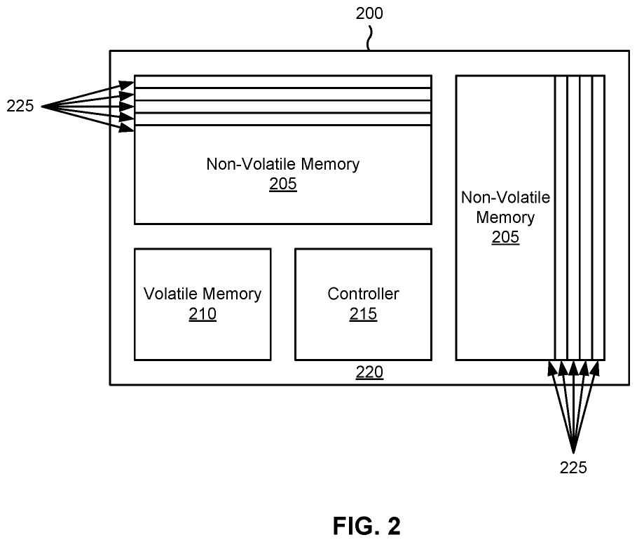

FIG. 2 is a diagram of an example memory device 200 that may be manufactured using techniques described herein. The memory device 200 is an example of the apparatus 100 described above in connection with FIG. 1. The memory device 200 may be any electronic device configured to store data in memory. In some implementations, the memory device 200 may be an electronic device configured to store data persistently in non-volatile memory 205. For example, the memory device 200 may be a hard drive, an SSD, a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, and/or an embedded multimedia card (eMMC) device.

As shown, the memory device 200 may include non-volatile memory 205, volatile memory 210, and a controller 215. The components of the memory device 200 may be mounted on or otherwise disposed on a substrate 220. In some implementations, the non-volatile memory 205 includes stacked semiconductor dies 225, as described above in connection with FIG. 1.

The non-volatile memory 205 may be configured to maintain stored data after the memory device 200 is powered off. For example, the non-volatile memory 205 may include NAND memory or NOR memory. The volatile memory 210 may require power to maintain stored data and may lose stored data after the memory device 200 is powered off. For example, the volatile memory 210 may include one or more latches and/or RAM, such as DRAM and/or SRAM. As an example, the volatile memory 210 may cache data read from or to be written to non-volatile memory 205, and/or may cache instructions to be executed by the controller 215.

The controller 215 may be any device configured to communicate with the non-volatile memory 205, the volatile memory 210, and a host device (e.g., via a host interface of the memory device 200). For example, the controller 215 may include a memory controller, a system controller, an ASIC, an FPGA, a processor, a microcontroller, and/or one or more processing components. In some implementations, the memory device 200 may be included in a system that includes the host device. The host device may include one or more processors configured to execute instructions and store data in the non-volatile memory 205.

The controller 215 may be configured to control operations of the memory device 200, such as by executing one or more instructions (sometimes called commands). For example, the memory device 200 may store one or more instructions as firmware, and the controller 215 may execute those one or more instructions. Additionally, or alternatively, the controller 215 may receive one or more instructions from a host device via a host interface, and may execute those one or more instructions. For example, the controller 215 may transmit signals to and/or receive signals from the non-volatile memory 205 and/or the volatile memory 210 based on the one or more instructions, such as to transfer data to (e.g., write or program), to transfer data from (e.g., read), and/or to erase all or a portion of the non-volatile memory 205 (e.g., one or more memory cells, pages, sub-blocks, blocks, or planes of the non-volatile memory 205).

As indicated above, FIG. 2 is provided as an example. Other examples may differ from what is described with regard to FIG. 2. The number and arrangement of components shown in FIG. 2 are provided as an example. In practice, there may be additional components, fewer components, different components, or differently arranged components than those shown in FIG. 2.

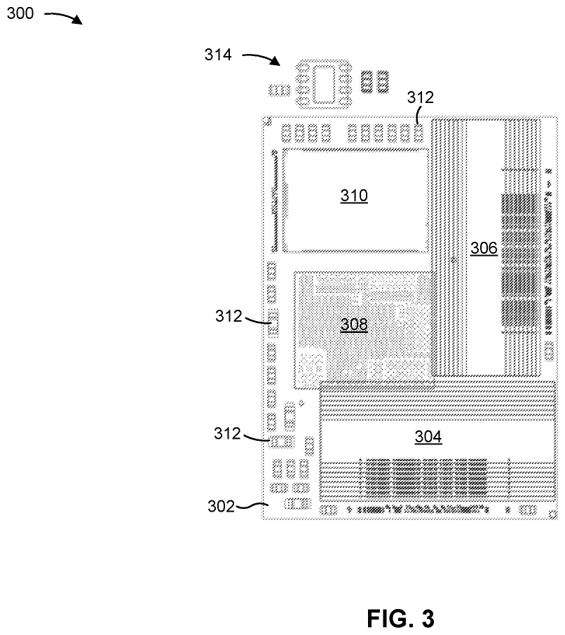

FIG. 3 is a diagram of an example apparatus 300. The apparatus 300 may include a substrate 302. Semiconductor devices 304, 306, 308, and 310 may be disposed on the substrate 302. The semiconductor devices 304, 306, 308, and 310 may include single-die semiconductor devices and/or stacked-die semiconductor devices, as described herein. In addition, a plurality of passive electronic components 312 may be disposed on the substrate 302. As described herein, usable space on the substrate 302 may be insufficient to fit all of the components of the apparatus 300. As a result, one or more passive electronic components 314 may be located off of the substrate 302 (e.g., outside of a semiconductor package), thereby increasing an overall footprint of the apparatus 300. Some implementations described herein address these and other issues.

As indicated above, FIG. 3 is provided as an example. Other examples may differ from what is described with respect to FIG. 3.

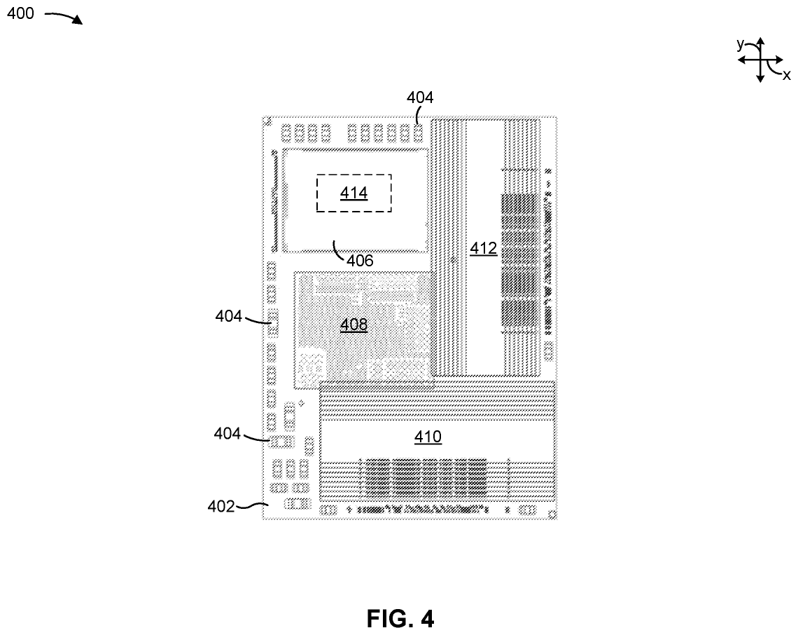

FIG. 4 is a diagram of an example apparatus 400. In some implementations, the apparatus 400 may correspond to the apparatus 100 and/or the memory device 200. For example, the apparatus 400 may be a semiconductor device assembly, such as a semiconductor package.

As shown in FIG. 4, the apparatus 400 may include a substrate 402 (e.g., a circuit board). The apparatus 400 may include one or more passive electronic components 404 connected to the substrate 402. For example, the passive electronic components 404 may be disposed on (e.g., arranged on) the substrate 402. The passive electronic components 404 may include one or more resistors, one or more inductors, and/or one or more capacitors. Additionally, or alternatively, the passive electronic components 404 may include one or more transformers, one or more diodes, one or more thermistors, one or more varactors, and/or one or more transducers, among other examples.

The apparatus 400 may include a first semiconductor die stack 406 and/or a second semiconductor die stack 408 disposed on the substrate 402. Additionally, the apparatus 400 may include a third semiconductor die stack 410 and a fourth semiconductor die stack 412. While the apparatus 400 is shown with four semiconductor die stacks, a different quantity of semiconductor die stacks may be employed in the apparatus 400 (e.g., a single die stack, two die stacks, three die stacks, etc.). Each semiconductor die stack 406, 408, 410, 412 may include a single semiconductor die (e.g., a semiconductor die stack that includes only one semiconductor die) or multiple semiconductor dies. In some implementations, at least two of the semiconductor die stacks 406, 408, 410, 412 may have different heights from each other. For example, a height of the first semiconductor die stack 406 may be approximately 120 micrometers (μm), a height of the second semiconductor die stack 408 may be approximately 130 μm, and heights of the third semiconductor die stack 410 and the fourth semiconductor die stack 412 may be approximately 520 μm. In some implementations, a semiconductor die stack 406, 408, 410, 412 may be configured as a controller, a memory device, and/or another type of semiconductor device.

The semiconductor die stacks 406, 408, 410, 412 may be electrically connected to the substrate 402. For example, the apparatus 400 may include one or more wire bonds (not shown) from the first semiconductor die stack 406 (e.g., from a semiconductor die thereof) to the substrate 402. As another example, the first semiconductor die stack 406 (e.g., a semiconductor die thereof) may be in a direct chip attachment configuration (e.g., a flip chip bonding configuration) with the substrate 402.

In some implementations, a passive electronic component 414 (represented in FIG. 4 by dashed lines) may be disposed on the first semiconductor die stack 406. For example, a plurality of passive electronic components 414 may be disposed on the first semiconductor die stack 406. For example, the passive electronic component 414 may be disposed on a semiconductor die (e.g., a topmost semiconductor die that is furthest from the substrate 402) of the first semiconductor die stack 406. Because the passive electronic component 414 may otherwise be located off of the substrate 402, as described herein, locating the passive electronic component 414 on the first semiconductor die stack 406 may reduce an overall footprint of the apparatus 400, thereby facilitating miniaturization of the apparatus 400. The passive electronic component 414 may include a resistor, an inductor, and/or a capacitor (e.g., the plurality of passive electronic components 414 may include one or more of any of the foregoing components). Additionally, or alternatively, the passive electronic component 414 may include a transformer, a diode, thermistor, a varactor, and/or a transducer, among other examples (e.g., the plurality of passive electronic components 414 may include one or more of any of the foregoing components).

In some implementations, the first semiconductor die stack 406, on which the passive electronic component 414 is disposed, may be a shortest (e.g., thinnest) semiconductor die stack of the apparatus 400. For example, a height of the first semiconductor die stack 406 may be shorter than a height of the second semiconductor die stack 408 (as well as heights of the third semiconductor die stack 410 and the fourth semiconductor die stack 412), as described herein. In this way, an overall height of the apparatus 400 may be minimized, thereby facilitating miniaturization of the apparatus 400. In some implementations, a height of the first semiconductor die stack 406 may be taller than a height of the second semiconductor die stack 408 (and/or heights of the third semiconductor die stack 410 and the fourth semiconductor die stack 412). In other words, the first semiconductor die stack 406, on which the passive electronic component 414 is disposed, may not be a shortest semiconductor die stack of the apparatus 400. In addition to the passive electronic component 414 on the first semiconductor die stack 406, in some implementations, one or more additional passive electronic components (not shown) may be disposed on the second semiconductor die stack 408, the third semiconductor die stack 410, and/or the fourth semiconductor die stack 412.

By placing passive electronic components on one or more semiconductor die stacks, an overall footprint associated with the apparatus 400 may be reduced, thereby facilitating miniaturization of a device that includes the apparatus 400. Moreover, a greater quantity of passive electronic components may be used in the apparatus 400, thereby facilitating enhancements to the complexity, operation, and/or functionality of the apparatus 400. Furthermore, the apparatus 400 may have an increased amount of free space on the substrate 402 that may be used for routing, thereby improving a routing efficiency and performance of the apparatus 400.

As indicated above, FIG. 4 is provided as an example. Other examples may differ from what is described with respect to FIG. 4.

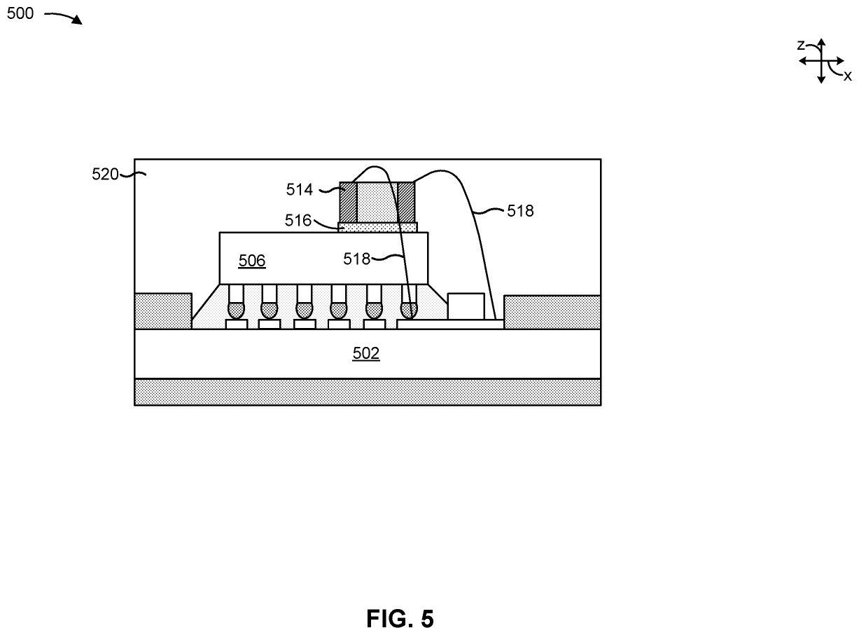

FIG. 5 is a diagram of an example apparatus 500. In some implementations, the apparatus 500 may correspond to the apparatus 400, or a portion thereof. For example, the apparatus 500 may be a semiconductor device assembly, such as a semiconductor package.

The apparatus 500 may include a substrate 502, which may correspond to, or may be similar to, the substrate 402 described herein. The apparatus 500 may include, disposed on the substrate 502, a semiconductor die stack 506, which may correspond to, or may be similar to, the first semiconductor die stack 406 described herein. In some implementations, as shown, the semiconductor die stack 506 (e.g., a semiconductor die thereof) may be electrically connected to the substrate 502 in a direct chip attachment configuration, as described herein. However, in some other implementations, the semiconductor die stack 506 (e.g., a semiconductor die thereof) may be electrically connected to the substrate 502 by one or more wire bonds, as described herein. As shown, the apparatus 500 may include a passive electronic component 514 (e.g., one or more passive electronic components 514), which may correspond to, or may be similar to, the passive electronic component 414 described herein. The passive electronic component 514 may be disposed on the semiconductor die stack 506 (e.g., on a semiconductor die, such as a topmost semiconductor die, thereof).

In some implementations, that apparatus 500 may include an insulating layer 516 between the semiconductor die stack 506 (e.g., a semiconductor die, such as a topmost semiconductor die, thereof) and the passive electronic component 514. For example, the insulating layer 516 may be disposed on a surface (e.g., a top-facing surface) of a semiconductor die (e.g., a topmost semiconductor die) of the semiconductor die stack 506, and the passive electronic component 514 may be disposed on the insulating layer 516. In this way, the passive electronic component 514 may be arranged on the semiconductor die stack 506 regardless of whether the semiconductor die stack 506 uses wire bonding or flip chip bonding for electrical connection to the substrate 502. For example, the surface of the semiconductor die, facing the passive electronic component 514, may be configured to be electrically active (e.g., one or more wire bonds to the substrate 502 may connect to the surface). As another example, the surface of the semiconductor die, facing the passive electronic component 514, may be configured to be electrically inactive (e.g., the semiconductor die stack 506 is in a direct chip attachment configuration with the substrate 502). The insulating layer 516 may be a die attach film (DAF) layer or another layer that provides electrical insulation. For example, the insulating layer 516 may comprise, consist of, or consist essentially of a polyimide adhesive, an epoxy adhesive, and/or an acrylic adhesive, among other examples.

The passive electronic component 514 may be electrically connected to the substrate 502. In some implementations, the apparatus 500 may include one or more wire bonds 518 from the passive electronic component 514 to the substrate 502 (e.g., to one or more bond pads of the substrate 502). To supply sufficient current to the passive electronic component 514, the wire bonds 518 may utilize thick wire up to 100 μm in diameter. For example, a current-carrying capacity of a wire bond 518 may be greater than a current-carrying capacity of another wire bond from the semiconductor die stack 506 (e.g., from a semiconductor die thereof) to the substrate 502. In this way, the passive electronic component 514 may be electrically connected to the substrate 502 in a manner that uses a smaller footprint than may have otherwise been used if the passive electronic component 514 were arranged directly on the substrate 502, thereby improving routing of the substrate 502, as described herein.

The apparatus 500 may include a casing 520 that surrounds the semiconductor die stack 506 (e.g., one or more semiconductor dies thereof). The casing 520 may also surround wire bonding, one or more additional semiconductor die stacks, and/or passive electronic components arranged on the substrate 502, such as those described in connection with FIG. 4. In some implementations, the passive electronic component 514 (e.g., all of passive electronic components 514) may be entirely within the casing 520, as shown. That is, a height of the passive electronic component 514 may be less than a top mold clearance, for the casing 520, from a top of the semiconductor die stack 506. In some implementations, at least a portion of the passive electronic component 514 (e.g., one or more of the passive electronic components 514) may be outside of the casing 520 (e.g., the portion of the passive electronic component 514 may be exposed outside of the casing 520). That is, a height of the passive electronic component 514 may be greater than a top mold clearance, for the casing 520, from a top of the semiconductor die stack 506.

As indicated above, FIG. 5 is provided as an example. Other examples may differ from what is described with respect to FIG. 5.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

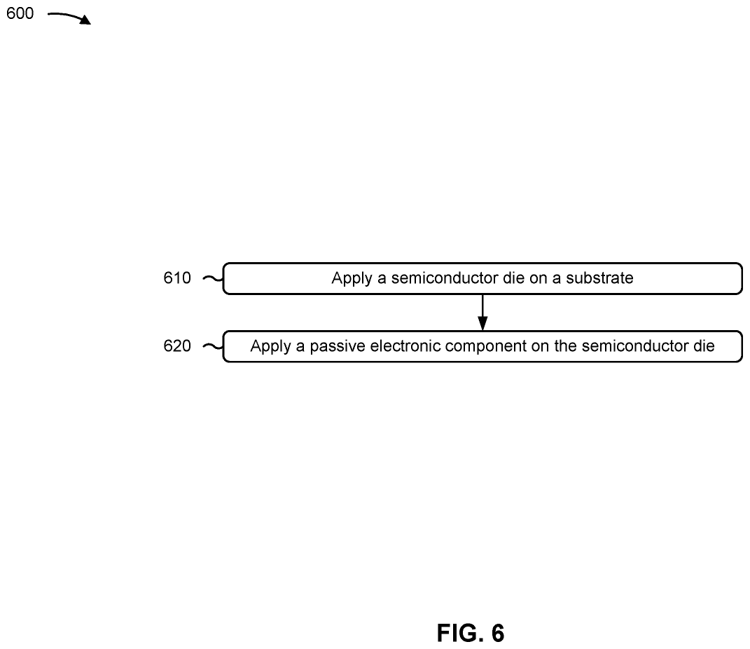

FIG. 6 is a flowchart of an example method 600 of forming an integrated assembly or memory device having a passive electronic component on a semiconductor die. In some implementations, one or more process blocks of FIG. 6 may be performed by various semiconductor manufacturing equipment.

As shown in FIG. 6, the method 600 may include applying a semiconductor die on a substrate (block 610). As further shown in FIG. 6, the method 600 may include applying a passive electronic component on the semiconductor die (block 620).

The method 600 may include additional aspects, such as any single aspect or any combination of aspects described below and/or in connection with one or more other methods described elsewhere herein.

In a first aspect, the method 600 includes applying an insulating layer on a surface of the semiconductor die, where the insulating layer is between the semiconductor die and the passive electronic component.

In a second aspect, alone or in combination with the first aspect, the method 600 includes placing one or more wire bonds from the passive electronic component to the substrate.

In a third aspect, alone or in combination with one or more of the first and second aspects, the method 600 includes applying the substrate to a circuit board.

Although FIG. 6 shows example blocks of the method 600, in some implementations, the method 600 may include additional blocks, fewer blocks, different blocks, or differently arranged blocks than those depicted in FIG. 6. In some implementations, the method 600 may include forming the apparatus 400 and/or the apparatus 500, an integrated assembly that includes the apparatus 400 and/or the apparatus 500, any part described herein of the apparatus 400 and/or the apparatus 500, and/or any part described herein of an integrated assembly that includes the apparatus 400 and/or the apparatus 500. For example, the method 600 may include forming one or more of the parts 402, 404, 406, 408, 410, 412, 414, 502, 506, 514, 516, 518, and/or 520.

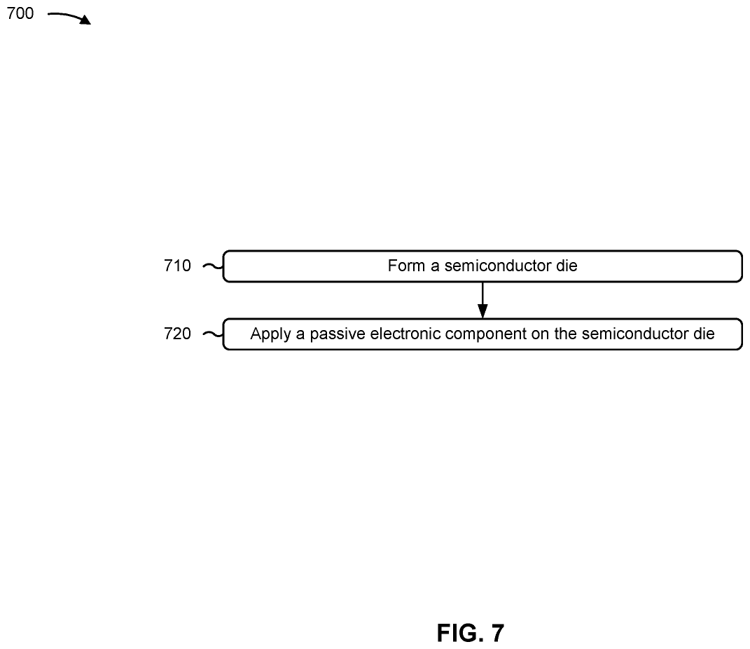

FIG. 7 is a flowchart of an example method 700 of forming an integrated assembly or memory device having a passive electronic component on a semiconductor die. In some implementations, one or more process blocks of FIG. 7 may be performed by various semiconductor manufacturing equipment.

As shown in FIG. 7, the method 700 may include forming a semiconductor die (block 710). As further shown in FIG. 7, the method 700 may include applying a passive electronic component on the semiconductor die (block 720).

The method 700 may include additional aspects, such as any single aspect or any combination of aspects described below and/or in connection with one or more other methods described elsewhere herein.

In a first aspect, forming the semiconductor die includes forming a semiconductor die stack that includes the semiconductor die.

In a second aspect, alone or in combination with the first aspect, the method 700 includes applying an insulating layer on a surface of the semiconductor die, where the insulating layer is between the semiconductor die and the passive electronic component.

Although FIG. 7 shows example blocks of the method 700, in some implementations, the method 700 may include additional blocks, fewer blocks, different blocks, or differently arranged blocks than those depicted in FIG. 7. In some implementations, the method 600 may include forming the apparatus 400 and/or the apparatus 500, an integrated assembly that includes the apparatus 400 and/or the apparatus 500, any part described herein of the apparatus 400 and/or the apparatus 500, and/or any part described herein of an integrated assembly that includes the apparatus 400 and/or the apparatus 500. For example, the method 600 may include forming one or more of the parts 402, 404, 406, 408, 410, 412, 414, 502, 506, 514, 516, 518, and/or 520.

In some implementations, a semiconductor device assembly includes a substrate; a semiconductor die disposed on the substrate; a passive electronic component disposed on the semiconductor die; and an insulating layer between the semiconductor die and the passive electronic component.

In some implementations, a semiconductor package includes a substrate; a semiconductor die disposed on the substrate; and a passive electronic component disposed on the semiconductor die.

In some implementations, a semiconductor device assembly includes a substrate; one or more passive electronic components disposed on the substrate; a first semiconductor die stack disposed on the substrate; a second semiconductor die stack disposed on the substrate; and a passive electronic component disposed on the first semiconductor die stack.

In some implementations, an apparatus includes a substrate; a semiconductor die disposed on the substrate, the semiconductor die being electrically connected to the substrate; and a passive electronic component disposed on the semiconductor die, the passive electronic component being electrically connected to the substrate.

In some implementations, a method includes applying a semiconductor die on a substrate; and applying a passive electronic component on the semiconductor die.

In some implementations, a method includes forming a semiconductor die; and applying a passive electronic component on the semiconductor die.

The following provides an overview of some Aspects of the present disclosure:

Aspect 1: A semiconductor device assembly, comprising: a substrate; a semiconductor die disposed on the substrate; a passive electronic component disposed on the semiconductor die; and an insulating layer between the semiconductor die and the passive electronic component.

Aspect 2: The semiconductor device assembly of Aspect 1, wherein the passive electronic component is a resistor, an inductor, or a capacitor.

Aspect 3: The semiconductor device assembly of any of Aspects 1-2, wherein the insulating layer is a die attach film.

Aspect 4: The semiconductor device assembly of any of Aspects 1-3, wherein a surface of the semiconductor die, facing the passive electronic component, is configured to be electrically active.

Aspect 5: The semiconductor device assembly of any of Aspects 1-3, wherein a surface of the semiconductor die, facing the passive electronic component, is configured to be electrically inactive.

Aspect 6: The semiconductor device assembly of any of Aspects 1-5, wherein the semiconductor die is a topmost semiconductor die of a semiconductor die stack disposed on the substrate.

Aspect 7: The semiconductor device assembly of Aspect 6, wherein the semiconductor die stack is a first semiconductor die stack, and wherein the semiconductor device assembly further comprises a second semiconductor die stack.

Aspect 8: The semiconductor device assembly of Aspect 7, wherein a height of the first semiconductor die stack is shorter than a height of the second semiconductor die stack.

Aspect 9: The semiconductor device assembly of Aspect 7, wherein a height of the first semiconductor die stack is taller than a height of the second semiconductor die stack.

Aspect 10: The semiconductor device assembly of any of Aspects 7-9, further comprising: one or more passive electronic components disposed on the substrate.

Aspect 11: The semiconductor device assembly of any of Aspects 1-10, wherein the semiconductor die is configured as a controller.

Aspect 12: The semiconductor device assembly of any of Aspects 1-11, wherein the semiconductor die is configured as a memory device.

Aspect 13: A semiconductor package, comprising: a substrate; a semiconductor die disposed on the substrate; and a passive electronic component disposed on the semiconductor die.

Aspect 14: The semiconductor package of Aspect 13, wherein the passive electronic component is a resistor.

Aspect 15: The semiconductor package of any of Aspects 13-14, wherein the passive electronic component is an inductor.

Aspect 16: The semiconductor package of any of Aspects 13-15, wherein the passive electronic component is a capacitor.

Aspect 17: The semiconductor package of any of Aspects 13-16, wherein the passive electronic component is one of a plurality of passive electronic components disposed on the semiconductor die.

Aspect 18: The semiconductor package of any of Aspects 13-17, further comprising: a casing that surrounds the semiconductor die.

Aspect 19: The semiconductor package of Aspect 18, wherein the passive electronic component is entirely within the casing.

Aspect 20: The semiconductor package of Aspect 18, wherein at least a portion of the passive electronic component is outside of the casing.

Aspect 21: A semiconductor device assembly, comprising: a substrate; one or more passive electronic components disposed on the substrate; a first semiconductor die stack disposed on the substrate; a second semiconductor die stack disposed on the substrate; and a passive electronic component disposed on the first semiconductor die stack.

Aspect 22: The semiconductor device assembly of Aspect 21, further comprising: an insulating layer between the first semiconductor die stack and the passive electronic component.

Aspect 23: The semiconductor device assembly of any of Aspects 21-22, wherein the first semiconductor die stack is a shortest semiconductor die stack of the semiconductor device assembly.

Aspect 24: The semiconductor device assembly of any of Aspects 21-23, further comprising: an additional passive electronic component disposed on the second semiconductor die stack.

Aspect 25: An apparatus, comprising: a substrate; a semiconductor die disposed on the substrate, the semiconductor die being electrically connected to the substrate; and a passive electronic component disposed on the semiconductor die, the passive electronic component being electrically connected to the substrate.

Aspect 26: The apparatus of Aspect 25, further comprising: an insulating layer between the semiconductor die and the passive electronic component.

Aspect 27: The apparatus of any of Aspects 25-26, further comprising: one or more wire bonds from the passive electronic component to the substrate.

Aspect 28: The apparatus of Aspect 27, wherein a current-carrying capacity of a wire bond, of the one or more wire bonds, is greater than a current-carrying capacity of another wire bond from the semiconductor die to the substrate.

Aspect 29: The apparatus of any of Aspects 25-28, further comprising: one or more wire bonds from the semiconductor die to the substrate.

Aspect 30: The apparatus of any of Aspects 25-28, wherein the semiconductor die is in a direct chip attachment configuration with the substrate.

Aspect 31: A method, comprising: applying a semiconductor die on a substrate; and applying a passive electronic component on the semiconductor die.

Aspect 32: The method of Aspect 31, further comprising: applying an insulating layer on a surface of the semiconductor die, wherein the insulating layer is between the semiconductor die and the passive electronic component.

Aspect 33: The method of any of Aspects 31-32, further comprising: placing one or more wire bonds from the passive electronic component to the substrate.

Aspect 34: The method of any of Aspects 31-33, further comprising: applying the substrate to a circuit board.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.”

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor device assembly, comprising:
a substrate;
a semiconductor die disposed on the substrate;
a passive electronic component disposed on the semiconductor die; and
an insulating layer between the semiconductor die and the passive electronic component.

2. The semiconductor device assembly of claim 1, wherein the passive electronic component is a resistor, an inductor, or a capacitor.

3. The semiconductor device assembly of claim 1, wherein the insulating layer is a die attach film.

4. The semiconductor device assembly of claim 1, wherein a surface of the semiconductor die, facing the passive electronic component, is configured to be electrically active.

5. The semiconductor device assembly of claim 1, wherein a surface of the semiconductor die, facing the passive electronic component, is configured to be electrically inactive.

6. The semiconductor device assembly of claim 1, wherein the semiconductor die is a topmost semiconductor die of a semiconductor die stack disposed on the substrate.

7. The semiconductor device assembly of claim 6, wherein the semiconductor die stack is a first semiconductor die stack, and
wherein the semiconductor device assembly further comprises a second semiconductor die stack.

8. The semiconductor device assembly of claim 7, wherein a height of the first semiconductor die stack is shorter than a height of the second semiconductor die stack.

9. The semiconductor device assembly of claim 7, wherein a height of the first semiconductor die stack is taller than a height of the second semiconductor die stack.

10. The semiconductor device assembly of claim 7, further comprising:
one or more passive electronic components disposed on the substrate.

11. A semiconductor package, comprising:
a substrate;
a semiconductor die disposed on the substrate; and
a passive electronic component disposed on the semiconductor die.

12. The semiconductor package of claim 11, wherein the passive electronic component is a resistor, an inductor, or a capacitor.

13. The semiconductor package of claim 11, wherein the passive electronic component is one of a plurality of passive electronic components disposed on the semiconductor die.

14. The semiconductor package of claim 11, further comprising:
a casing that surrounds the semiconductor die.

15. The semiconductor package of claim 14, wherein the passive electronic component is entirely within the casing.

16. The semiconductor package of claim 14, wherein at least a portion of the passive electronic component is outside of the casing.

17. A semiconductor device assembly, comprising:
a substrate;
one or more passive electronic components disposed on the substrate;
a first semiconductor die stack disposed on the substrate;
a second semiconductor die stack disposed on the substrate; and
a passive electronic component disposed on the first semiconductor die stack.

18. The semiconductor device assembly of claim 17, further comprising:
an insulating layer between the first semiconductor die stack and the passive electronic component.

19. The semiconductor device assembly of claim 17, wherein the first semiconductor die stack is a shortest semiconductor die stack of the semiconductor device assembly.

20. The semiconductor device assembly of claim 17, further comprising:
an additional passive electronic component disposed on the second semiconductor die stack.
